(19) United States
(12) Patent Application Publication
(10) Pub. No.: US 2016/0139184 A1
(43) Pub. Date: May 19, 2016

(54) VOLTAGE TEST APPARATUS AND METHOD

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YONG-ZHAO HUANG, Wuhan (CN); YI-HUNG PENG, New Taipei (TW)

(21) Appl. No.: 14/576,464

(22) Filed: Dec. 19, 2014

(30) Foreign Application Priority Data
Nov. 18, 2014 (CN) 201410657175.X

(51) Int. Cl. G01R 19/25

(52) U.S. Cl. CPC G01R 19/2503

(57) ABSTRACT

The disclosure provides a voltage test apparatus for CPU serial voltage identification signal including a collecting module, a detecting module, and a processing module. The collecting module obtains the SVID signal from the CPU, the detecting module obtains the work voltage from the CPU. The processing module obtains the SVID signal and the work voltage from the collecting module and the processing module. The processing module converts the SVID signal to an analog voltage. The processing module further compares the work voltage with the analog voltage. The disclosure also provides a testing method for CPU SVID signal.

### FIELD

The subject matter herein generally relates to a test apparatus and a method, and particularly relates to a test apparatus and a method for testing a serial voltage identification definition (SVID) signal of a central processing unit (CPU).

### BACKGROUND

A voltage regulator module obtains a SVID signal from a CPU and outputs a work voltage to the CPU according to the obtained SVID signal. The SVID signal and the work voltage must be correct and therefore need to be tested.

### BRIEF DESCRIPTION OF THE DRAWINGS

Implementations of the present technology will now be described, by way of example only, with reference to the attached figures.

FIG. 1 is a block diagram of an example embodiment of a test apparatus of the present disclosure.

FIG. 2 is a flow chart of an example embodiment of a test method of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrates details and features. The description is not to be considered as limiting the scope of the embodiments described herein.

A definition that applies throughout this disclosure will now be presented.

The term “comprising” means “including, but not necessarily limited to”; it specifically indicates open-ended inclusion or membership in a so-described combination, group, series and the like.

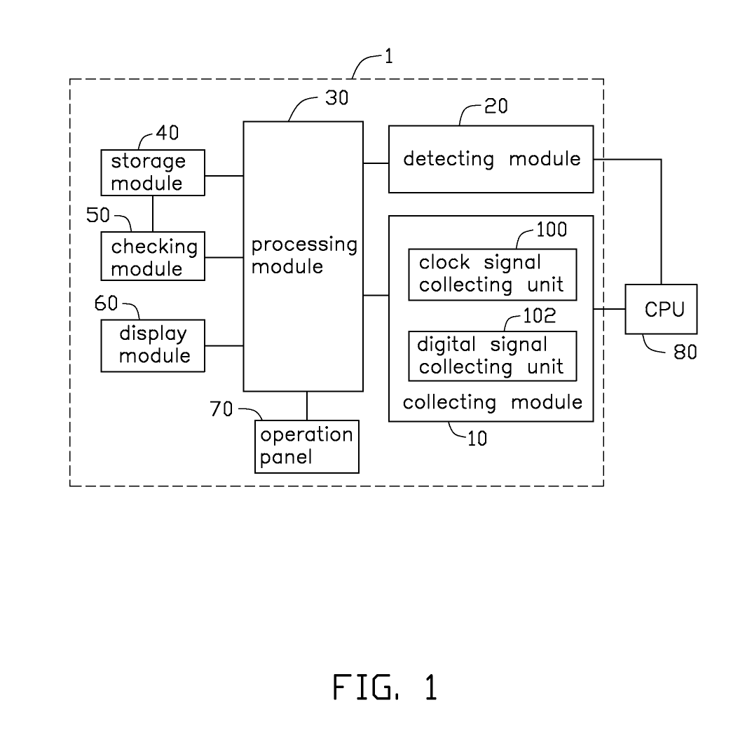

FIG. 1 illustrates a test apparatus of the present disclosure. A test apparatus 1 can test a SVID signal of a CPU. The test apparatus 1 in accordance with an exemplary embodiment includes a collecting module 10, a detecting module 20, a processing module 30, a storage module 40, a checking module 50, a display module 60, and an operation panel 70.

In one embodiment, the operation panel 70 can input a start command to turn on the test apparatus. The collecting module 10 can obtain the SVID signal from the CPU 80, and include a clock signal collecting unit 100 and a digital signal collecting unit 102. The clock signal collecting unit 100 can obtain clock signal of the SVID signal from the CPU 80, and transmit the clock signal to the processing module 30. The digital signal collecting unit 102 can obtain digital signal of the SVID signal from the CPU 80, and transmit the digital signal to the processing module 30.

The detecting module 20 can detect a working voltage of the CPU 80, and transmit the working voltage to the processing module 30.

In one embodiment, the processing module 30 can obtain the work voltage from the detecting module 20, and the SVID signal from the collecting module 10. The processing module 30 can convert the digital signal into a binary signal. For example, the cycle of time between t=0 and t=0.05 s is a clock cycle, the processing module 30 determines the level state of the digital signal in the clock cycle. When the digital signal is at a high level in the clock cycle, the processing module 30 converts the digital signal to logic 1, when the digital signal is at a low level in the clock signal cycle, the processing module 30 converts the digital signal to logic 0. In this way, the processing module 30 converts the digital signal transmitted by the collecting module 10 to the binary signal, and transmits the binary signal to the checking module 50.

In one embodiment, the checking module 50 obtains the binary signal from the processing module 30, and checks the binary signal. In the embodiment, the checking module 50 can use a memory parity check method to check the binary signal. In other embodiments, the checking module 50 also can use a results contrast method to check the binary signal.

In the embodiment, the checking module 50 outputs the binary signal to the storage module 40 and the processing module 30, the processing module 30 can obtain the binary signal from the storage module 40 at anytime.

In the embodiment, the processing module 30 obtains the binary signal from the checking module 50, and converts the binary signal to an analog voltage according to a SVID protocol. The processing module 30 compares the work voltage with the analog voltage and gets a comparison result, and controls the display module 60 to display the comparison result.

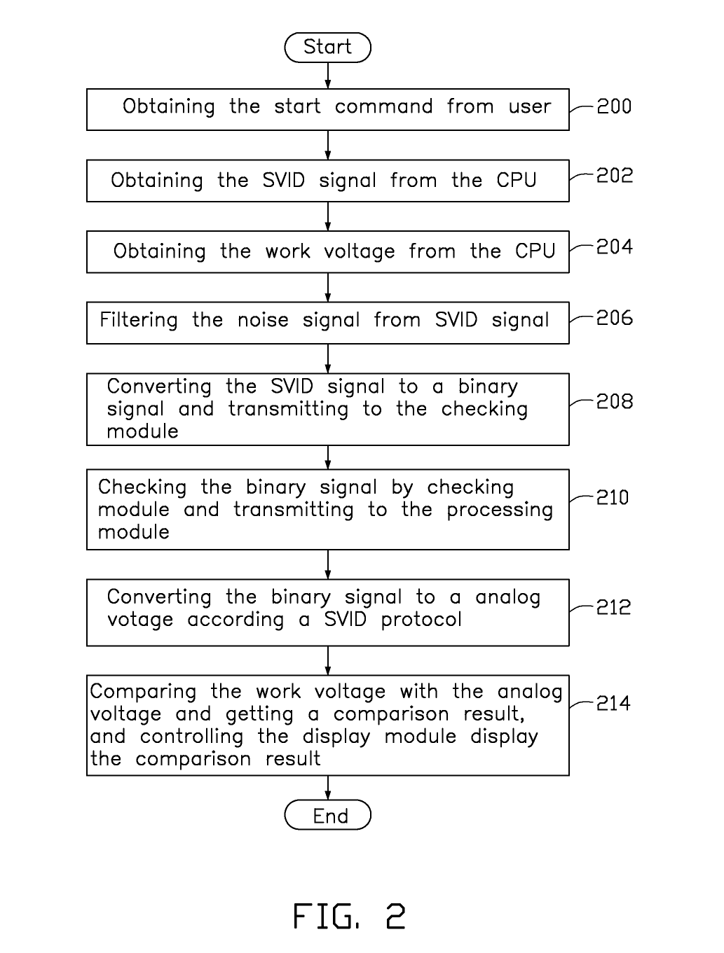

Referring to FIG. 2, a flowchart is presented in accordance with an example embodiment which is being thus illustrated. The example method is provided by way of example, as there are a variety of ways to carry out the method. The method described below can be carried out using the configurations illustrated in FIG. 1, for example, and various elements of these figures are referenced in explaining example method. Each block shown in FIG. 2 represents one or more processes, methods or subroutines, carried out in the test method. Additionally, the illustrated order of blocks is by example only and the order of the blocks can change according to the present disclosure. The test method can begin at block 200.

At block 200, the test apparatus starts working

At block 202, the collecting module 10 obtains the SVID signal from the CPU 80, and transmits the SVID signal to the processing module 30.

At block 204, the detecting module 20 detects the work voltage 40 from the CPU 80, and transmits the work voltage to the processing module 30.

At block 206, the processing module 30 filters noise signals in the SVID signal, to obtain accurate digital signals and clock signals.

At block 208, the processing module 30 converts the digital signals to a binary signal according to the clock signal transmitted by the collecting module 10. For example, the cycle of time between t=0 and t=0.05 s is a clock cycle, the processing module 30 determines the level state of the digital signal in the clock cycle. When the digital signal is at a high level in the clock cycle, the processing module 30 converts the digital signal to logic 1, when the digital signal is at a low level in the clock signal cycle, the processing module 30 converts the digital signal to logic 0. In this way, the processing module 30 converts the digital signal transmitted by the collecting module 10 to the binary signal, and transmits the binary signal to the checking module 50.

At block 210, the checking module 50 obtains the binary signal from the processing module 30, and checks the binary signal, and the checking module 50 outputs the binary signal to the storage module 40 and the processing module 30, the processing module 30 can obtain the binary signal from the storage module 40 at anytime. In the embodiment, the checking module 50 can use a memory parity check method to check the binary signal. In other embodiments, the checking module 50 also can use a results contrast method to check the binary signal.

At block 212, the processing module 30 converts the binary signal to a analog voltage according to a SVID protocol.

At block 214, the processing module 30 compares the work voltage with the analog voltage and gets a comparison result, and controls the display module 60 display the comparison result.

While the disclosure has been described by way of example and in terms of a preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A test apparatus comprising:
a display module;
a collecting module obtaining a serial voltage identification definition (SVID) signal from a central processing unit (CPU);
a detecting module obtaining a work voltage from the CPU; and
a processing module obtaining the SVID signal from the collecting module and the work voltage detected by the detecting module, the processing module converting the SVID signal to a binary signal, and converting the binary signal to an analog voltage according to a SVID protocol, the processing module further comparing the work voltage with the analog voltage to obtain a comparison result, and controlling the display module to display the comparison result.

2. The test apparatus of claim 1, wherein the test apparatus further comprises a checking module and a storage module, the checking module checks the binary signal and stores the binary signal to the storage module, and the processing module reads the binary signal in the storage module.

3. The test apparatus of claim 1, wherein the collecting module further comprises a clock signal collecting unit and a digital signal collecting unit, the clock signal collecting unit obtains clock signal of the SVID signal from the CPU, and transmits the clock signal to the processing module, the digital signal collecting unit obtains digital signal of the SVID signal from the CPU, and transmits the digital signal to the processing module.

4. A test method comprising:
obtaining a serial voltage identification definition (SVID) signal from a central processing unit (CPU) by a collecting module, and transmitting the SVID signal to a processing module;
detecting a work voltage from the CPU by a detecting module;
obtaining the SVID signal from the collecting module and the work voltage from the detecting module by the processing module, and converting the SVID signal to a binary signal;
converting the binary signal to an analog voltage by the processing module according to a SVID protocol, comparing the analog voltage with the work voltage, and obtaining a comparison result; and
controlling a display module display the comparison result by the processing module.
